(19) United States
(12) Patent Application Publication
(10) Pub. No.: US 2026/0160825 A1
(43) Pub. Date: Jun. 11, 2026

(54) DIAGNOSING RAPIDLY DEGRADING LITHIUM ION BATTERY CELLS USING DIRECT CURRENT INTERNAL RESISTANCE

(71) Applicant: LG ENERGY SOLUTION, LTD., Seoul (KR)

(72) Inventors: Seonyoung JEGAL, Daejeon (KR); Seunghyun KIM, Daejeon (KR); Mikyung CHUNG, Daejeon (KR); Min Jun KIM, Daejeon (KR); Dongwook KOH, Daejeon (KR); Jay Hyung Lee, Los Angeles, CA (US); Jaewook LEE, Daejeon (KR)

(21) Appl. No.: 19/078,958

(22) Filed: Mar. 13, 2025

Related U.S. Application Data
(60) Provisional application No. 63/729,193, filed on Dec. 6, 2024.

(51) Int. Cl. G01R 31/392; B60L 58/12; B60L 58/16; G01R 31/3842; G01R 31/389; G01R 31/396; H01M 10/42

(52) U.S. Cl. CPC G01R 31/392; B60L 58/12; B60L 58/16; G01R 31/3842; G01R 31/389; G01R 31/396; H01M 10/425; H01M 10/4285; H01M 2010/4271; H01M 2220/20

(57) ABSTRACT

Systems and methods for diagnosing rapidly degrading battery cells are disclosed. A direct current (DC) pulse is applied to a battery cell during at least one of a charging process or a discharging process. The change in voltage over time in response to the applied DC pulse is measured to determine direct current internal resistance (DCIR). A charge transfer resistance (R_{ct}) component of the DCIR is isolated by excluding an ohmic resistance (Rₒ) component from the DCIR. The battery cell is diagnosed as rapidly degrading by predicting at least one state of health (SOH) of the battery cell indicative of rapid cell degradation.

### CROSS-REFERENCE TO RELATED APPLICATION

This application claims priority to and the benefit of U.S. Provisional Application 63/729,193 filed on Dec. 6, 2024, the disclosure of which is incorporated herein by reference.

### TECHNICAL FIELD

The present disclosure relates to accurately diagnosing and mitigating rapidly degrading battery cells.

### BACKGROUND

Batteries have become a critical component in modern energy management systems. Battery technology allows for the storage of excess electricity during periods of low demand and discharge of scarce electricity during high demand, thereby optimizing energy usage (by reducing the curtailment of solar and wind electricity), reducing reliance on fossil fuel-based power generation such as gas turbines or combustion vehicles, and mitigating the effects of climate change by reducing the release of greenhouse gases.

As lithium-ion batteries (LIBs) become integral to numerous applications, ensuring their safety is paramount. Research in this area has focused on estimating or predicting the state of health (SOH) of LIBs, a term that generally describes the capacity of a battery in a given cycle relative to its nominal capacity. Capacity degradation in LIBs occurs gradually due to side reactions during battery cycling. A battery is considered to have reached its end-of-life (EOL) when its SOH falls below 80%, indicating it is no longer safe for use.

Methods for estimating or predicting the SOH of LIBs can generally be divided into physics-based and data-driven approaches. Physics-based methods include the equivalent circuit model, which represents the battery's degradation elements as circuit components like resistors and capacitors; the empirical method, which simplifies complex degradation rates into empirical formulas; and the electrochemical model (EM), which precisely simulates the electrochemical behaviors inside a cell while aiming to manage computational costs. However, both the equivalent circuit and empirical methods struggle to fully capture complex degradation phenomena. The EM, while providing detailed insights, often involves numerous unknown parameters and substantial computational demands. These complexities can lead to inaccuracies, particularly when simulating scenarios with rapidly degrading cells.

Given these challenges, data-driven models are increasingly favored for predicting the lifetime characteristics of rapidly degrading LIBs under conditions such as rapid charge and discharge and severe operating environments. These models establish relationships between health indices (HIs) recorded during initial charge and discharge cycles and future SOH, enabling SOH predictions when new LIB data is provided. HIs are divided into direct health indices (DHIs), which are readily measurable during the cycling process, and refined health indices (RHIs), which require separate post-cycling measurements.

Typical direct health indices (DHIs) such as voltage, current, and temperature (VIT) are not directly linked to battery capacity. As a result, estimating or predicting SOH using these indices often requires the use of complex deep neural networks. However, accumulating sufficient battery cycling data up to EOL to effectively train these networks is costly and challenging, which limits the utility of DHIs alone for accurate future SOH prediction. Furthermore, there are significant differences between typical cycling experiments conducted in laboratories and the actual charge/discharge patterns in electric vehicles (EVs) To overcome these data limitations, research utilizing transfer learning is emerging. Despite this, transfer learning has not yet consistently delivered satisfactory performance when there are changes in battery composition or operating conditions, underscoring the need for simpler models in situations with limited cycling datasets.

RHIs are generally more strongly correlated with the SOH than DHIs, allowing for the use of simpler models for lifespan prediction, such as linear models. For instance, studies have demonstrated effective SOH prediction using simple models based on ratios such as dQ/dV. However, these variables are challenging to measure during actual electric vehicle (EV) operation, making it difficult for on-board battery management systems (BMS) to utilize the variables in real-time. Some research has explored using capacity as an input variable for SOH estimation. Capacity trend is a potent predictor of future battery performance and can be monitored during EV operation; however, accurately gauging capacity under real-world conditions is problematic, as it requires cycling the state of charge (SOC) from 0% to 100% each cycle.

Thus, while DHIs are easily measurable and commonly used, their weak direct correlation with SOH often necessitates complex modeling approaches. Conversely, RHIs have a strong correlation with SOH but pose significant challenges for real-time measurement in EVs. Identifying an input variable that is both easy to measure and closely related to SOH is crucial for enhancing user safety

Internal resistance (IR) is another indicator with a high correlation to capacity degradation, making it a significant term in battery analysis. Recognizing the importance of IR, several studies have aimed to predict IR directly using DHIs or RHIs as input variables. Additionally, researchers have incorporated IR-based terms into models for estimating or predicting SOH, typically using resistance measurements from electrochemical impedance spectroscopy (EIS). EIS is valued for its ability to differentiate between ohmic resistance (Rₒ), charge transfer resistance (R_{ct}), and polarization resistance (Rₚ) accurately, enabling the preservation and utilization of resistance terms closely associated with SOH. However, the practical application of EIS in EVs faces limitations, as it cannot be conducted during normal battery operation, presenting similar challenges as other RHIs in real-time EV diagnostics.

The background description provided herein is for the purpose of generally presenting context of the disclosure. Unless otherwise indicated herein, the materials described in this section are not prior art to the claims in this application and are not admitted to be prior art, or suggestions of the prior art, by inclusion in this section.

### SUMMARY

Considering the limitations described above, direct current internal resistance (DCIR) emerges as a viable alternative that can be measured during both charging and discharging when a constant current (CC) is applied. DCIR is typically calculated by analyzing the voltage change relative to the current change over a specific duration, such as the first 0.1s or 1s, using a pulse test at a given SOC during a hybrid pulse power characterization (HPPC) test in a reference performance test (RPT).

Unlike EIS, which requires alternating current, DCIR has the advantage of being measurable during the driving process since it uses direct current in a specific direction. Moreover, the EV charger generally sets the terminal SOC to a certain level, providing a degree of uniformity in SOC immediately after charging. Additionally, factors like c-rate and temperature, which can influence DCIR, tend to be consistent for the same driver, making it a meaningful input variable for direct use. It is also inferred that the SOC just before charging (after discharge) is similarly uniform across drivers. Notably, terms based on charge transfer resistance (R_{ct}), which are crucially linked to capacity degradation, do not significantly vary within the SOC range of 20% to 80%, suggesting minimal impact on the accuracy of a regression model.

Utilizing DCIR presents challenges, primarily in isolating the resistive components effectively since DC is only employed during cycling, and the sampling time can be relatively long. Furthermore, researchers must deduce which resistive term is predominant based on the measurement timescale, as different degradation mechanisms affect capacity fade under varying operating conditions. Although relatively few studies have focused on using DCIR-based terms as input variables for SOH estimation, there are notable examples. Sun et al. (Z. Sun, W. He, J. Wang, X. He, State of health estimation for lithium ion batteries with deep learning approach and direct current internal resistance, Energies 17 (11) (2024) 2487) developed a model using long short-term memory (LSTM) to estimate SOH using DCIR without separating the resistance components. Conversely, Van et al. (C. N. Van, D. T. Quang, Estimation of soh and internal resistances of lithium ion battery based on Istm network, International Journal of Electrochemical Science 18 (6) (2023) 100166.) used the ohmic resistance (Rₒ) derived from DCIR to estimate SOH, capitalizing on the fact that Rₒ is quickly measurable immediately following the pulse current application (within the first microseconds). Typically, studies either do not distinguish between the different resistive terms of DCIR by timescale, or they focus solely on Rₒ, which is simpler to measure. To knowledge, no research has yet employed the charge transfer resistance (R_{ct}) estimated via DCIR in rapidly degrading cells as the primary input variable. In scenarios where LIBs degrade slowly, the rates of increase in Rₒ within the electrolyte and Rat at the electrolyte-electrode interface are comparable, making traditional methods effective. However, in cases of rapid degradation due to accelerated side reactions, R_{ct} escalates more swiftly than Rₒ, which complicates accurate lifetime prediction of these cells using conventional approaches. Moreover, since resistance increases not only due to side reactions but also varies with operating conditions such as ambient temperature (T_{amb}) and pressure, it has been challenging to predict the lifetime characteristics by considering only the resistance changes attributable to side reactions.

To address these challenges, the present systems and methods leverage DCIR values, particularly those incorporating charge transfer resistance (R_{ct}), to predict the future state of health SOH of cells that degrade abruptly. It is feasible to isolate the sudden rises in resistance due to rapid side reactions, and these resistance increases exhibit high linearity and monotonicity with subsequent capacity fade. For this purpose, an EV pattern-based dataset is used and standards for abrupt capacity fade derived from previous research. 79 DCIR values are calculated from each RPT, where the Hybrid Pulse Power Characterization (HPPC) test is conducted at three different SOC levels. The linear correlations between DCIR and the last cycle SOH in each RPT cycle are calculated and compared between abruptly fading cells and normally degrading cells. From these analyses, a representative linear and sparse model is constructed using the elastic net (EN) method, with DCIR-based values as inputs. The model achieves a high prediction accuracy, with a root mean square error (RMSE) of approximately 1.3%, which outperforms more complex neural network-based models. Choosing a linear model over complex deep neural networks reflects the limited data available for abruptly fading cells in real-world EV scenarios, emphasizing the importance of simplicity in the modeling approach. Additionally, by employing a sparse model that selects a limited number of input variables, the informativeness of each variable can be determined and which are most predictive of SOH can be identified.

Accordingly, the present disclosure describes systems and methods for diagnosing rapidly degrading lithium-ion battery cells by leveraging direct current internal resistance DCIR as a diagnostic metric. The present systems and methods may identify significant deviations in DCIR patterns that indicate rapid degradation of battery cells, even before substantial capacity fade becomes apparent. DCIR may be measured at multiple state of charge (SOC) levels and timescales to extract resistance components such as ohmic resistance (Rₒ), charge transfer resistance (R_{ct}), and polarization resistance (Rₚ). Focus is placed on R_{ct} which correlates strongly with capacity degradation due to abrupt side reactions.

According to one aspect, the present disclosure is directed to a system for diagnosing rapidly degrading battery cells, comprising: a controller comprising a processor and a non-transitory memory storing computing instructions which when executed by the processor is configured to: (a) apply a direct current (DC) pulse to a battery cell during at least one of a charging process or a discharging process; (b) measure a change in voltage over time in response to the applied DC pulse to determine direct current internal resistance (DCIR); (c) isolate a charge transfer resistance (R_{ct}) component of the DCIR by excluding an ohmic resistance (Rₒ) component from the DCIR; and (d) diagnose the battery cell as rapidly degrading based on the R_{ct} component by predicting at least one state of health (SOH) of the battery cell indicative of rapid cell degradation.

In some cases, step (d) comprises: input the Ret component as a feature into a classifier to predict the at least one SOH of the battery cell at 180 charge-discharge cycles and 270 charge-discharge cycles; and diagnose the battery cell as rapidly degrading when a difference of the predicted SOH at 270 charge-discharge cycles and the predicted SOH at 180 charge-discharge cycles is at least about 2.5%.

In some cases, the classifier is a linear regression model that implements elastic net (EN) regression.

In some cases, the controller is configured to determine the DCIR at multiple timescales of the DC pulse including 0.1 seconds and at least one of 10 seconds or 30 seconds, and step (c) comprises subtracting the DCIR measured at 0.1 seconds from the DCIR measured at the at least one of 10 seconds or 30 seconds to exclude the Rₒ component and isolate the R_{ct} component.

In some cases, the controller is configured to apply the DC pulse after one or more of 0, 90, 180, or 270 charge-discharge cycles of the battery cell.

In some cases, the controller is configured to determine the DCIR at one or more timescales of the applied DC pulse, and the one or more timescales comprise 0.1 seconds, 1 seconds, 5 seconds, 10 seconds, 15 seconds, 20 seconds, 25 seconds, 30 seconds, or 60 seconds.

In some cases, the controller is configured to determine the DCIR at one or more states of charge (SOC) of the battery cell, and the one or more SOC comprise 10, 20%, 30%, 40%, 50%, 60%, 70%, 80% or 90%.

In some cases, the controller is configured to apply the DC pulse during a hybrid pulse power characterization (HPPC) test at multiple states of charge (SOC); and determine multiple values of the DCIR from the HPPC test, and the HPPC test comprises applying the DC pulse with at least two different currents.

In some cases, the at least two different currents comprise at least two of 0.5C, 1C, 1.5C, 2.0C, or 2.5C.

In some cases, the battery cell is configured to power an electric vehicle, and the controller is integrated with a battery management system (BMS) of the electric vehicle.

In some cases, the battery cell is configured to store renewable electricity generated by solar power or wind power in order to reduce reliance on fossil fuel-based power generation and mitigate climate change effects.

According to another aspect, the present disclosure is directed to a method for diagnosing rapidly degrading battery cells, comprising: (a) applying a direct current (DC) pulse to a battery cell during at least one of a charging process or a discharging process; (b) measuring a change in voltage over time in response to the applied DC pulse to determine direct current internal resistance (DCIR); (c) isolating a charge transfer resistance (R_{ct}) component of the DCIR by excluding an ohmic resistance (Rₒ) component from the DCIR; and (d) diagnosing the battery cell as rapidly degrading based on the R_{ct} component by predicting at least one state of health (SOH) of the battery cell indicative of rapid cell degradation.

According to another aspect, the present disclosure is directed to a non-transitory computer-readable medium having computer-executable instructions stored thereon that, in response to execution by a processor of a controller, cause the controller to perform operations for diagnosing rapidly degrading battery cells, the operations comprising: (a) applying a direct current (DC) pulse to a battery cell during at least one of a charging process or a discharging process; (b) measuring a change in voltage over time in response to the applied DC pulse to determine direct current internal resistance (DCIR); (c) isolating a charge transfer resistance (R_{ct}) component of the DCIR by excluding an ohmic resistance (Rₒ) component from the DCIR; and (d) diagnosing the battery cell as rapidly degrading based on the R_{ct} component by predicting at least one state of health (SOH) of the battery cell indicative of rapid cell degradation.

It should be noted that the technical effects obtainable through the present disclosure are not limited to the above-described effects, and other effects that are not mentioned herein will be clearly understood by those skilled in the art from the following descriptions.

### BRIEF DESCRIPTION OF THE DRAWINGS

The accompanying drawings illustrate exemplary aspects of the present disclosure and, together with the following detailed description, serve to provide further understanding of the technical spirit of the present disclosure. However, the present disclosure is not to be construed as being limited to the drawings.

FIG. 1 is a table showing a detailed profile of HPPC tests conducted during each RPT, indicating the number of DCIR measurements taken in each test, in accordance with an aspect of the present disclosure.

FIG. 2 is a plot showing the ratio of SOH degradation for tested cells over each 90-cycle interval, in accordance with an aspect of the present disclosure.

FIG. 3 is a table showing a distribution of SOH degradation rates of cells over the final 90 cycles under normal pressure and high pressure, in accordance with an aspect of the present disclosure.

FIG. 4 is a graph showing the average degradation rate of both Class 0 and Class 1 cells at 0, 90, 180 and 270 cycles, in accordance with an aspect of the present disclosure.

FIG. 5 is a table displaying the proportional distribution of Class 0 and Class 1 cells under varying pressures, temperatures, and charging modes, in accordance with an aspect of the present disclosure.

FIG. 6 is a graph showing an HPPC test process conducted with 2.5C, 1C long pulses at SOC=80, 50, 20%, in accordance with an aspect of the present disclosure.

FIG. 7A is a graph showing the change in voltage when a pulse current is applied and the resistance term associated with each change, in accordance with an aspect of the present disclosure.

FIG. 7B is a table showing the isolation of R_{ct} and Rₚ from Rₒ, in accordance with an aspect of the present disclosure.

FIG. 8 is a table showing the average regression performance of the SOH₂₇₀ linear regression model across five random seeds as a function of the l1-ratio, in accordance with an aspect of the present disclosure.

FIG. 9 is a table showing correlations between SOH₂₇₀ and the DCIR measured at each 90-cycle interval for both Class 0 and Class 1 cells, in accordance with an aspect of the present disclosure.

FIG. 10 is a table showing the state of charge (SOC) distribution of the top 20 DCIRs with Pearson and Spearman coefficients >0.5, in accordance with an aspect of the present disclosure.

FIG. 11 is a table showing the top 20 DCIRs by measurement duration, where values are adjusted by subtracting the initial 0.1s DCIR to isolate contributions beyond Rₒ, in accordance with an aspect of the present disclosure.

FIG. 12 is a diagram showing the determination of the normalization term Ratio_{avg}, in accordance with an aspect of the present disclosure.

FIGS. 13A and 13B are graphs showing a comparison of Ratio_{avg} and average SOH decrease in normal pressure cells across different ambient temperatures (T_{amb}) and charging modes, in accordance with an aspect of the present disclosure.

FIGS. 14A and 14B are graphs showing a comparison of Ratio_{avg} and average SOH decrease under pressure variations, focusing on ‘Power’ mode cells at T_{amb}=10° C. and T_{amb}=45° C., in accordance with an aspect of the present disclosure.

FIG. 15 is a flow diagram showing a method for diagnosing rapidly degrading battery cells, in accordance with an aspect of the present disclosure.

FIG. 16 is a diagram showing a system for diagnosing rapidly degrading battery cells including a controller, in accordance with an aspect of the present disclosure.

FIG. 17 is a diagram showing the integration of the controller of FIG. 16 in various applications, in accordance with an aspect of the present disclosure.

### DETAILED DESCRIPTION OF THE DISCLOSURE

The present disclosure may be variously changed and have various aspects, and the specific aspects disclosed herein in detail are used to facilitate an understanding of the present disclosure to those skilled in the art.

Therefore, it should be understood that there is no intention to limit the present disclosure to the particular aspects disclosed, and on the contrary, the present disclosure covers all modifications, equivalents, and alternatives falling within the spirit and scope of the present disclosure.

In this application, it should be understood that terms such as “include” or “have” are intended to indicate the presence of a feature, number, step, operation, component, part, or a combination thereof described on the specification, and they do not preclude the possibility of the presence or addition of one or more other features or numbers, steps, operations, components, parts or combinations thereof.

### Methodology

This section reviews the experimental dataset derived from electric vehicle driving patterns used in a previous study Lee et al. (J. Lee, S. Jegal, M. Chung, S. Kim, M. J. Kim, D.-W. Koh, J. H. Lee, Electric vehicle pattern-based battery cycling dataset and its application in predicting rapid degradation, chemrxiv.org (2024).), and outlines the criteria for rapid degradation, established from prior knowledge, and describes the DCIR terms extracted from each RPT cycle. Additionally, an EN model used for regression of the last cycle state of health (SOH₂₇₀) is introduced.

### Dataset Overview and Criteria for Identifying Rapidly Degrading Cells

The primary dataset used in the experiments of this disclosure includes cycling data from 143 LIB cells subjected to various operating conditions. These LIB cells have a Nickel-Cobalt-Manganese (NCM) cathode and a graphite anode. The discharge protocol followed a typical EV driving pattern, incorporating regenerative braking and periods of rest to simulate real EV conditions closely. Charging was conducted using a strategy that alternates between fast and slow modes, typical of EV charging systems. Specifically, the operating conditions varied across three ambient temperatures (T_{amb}=45, 25, 10° C.), three charging modes (fast charging labeled “Power,” “Normal” (specifically, the average c-rate in “Power” mode, SOC range is slightly higher than ‘Normal’ mode, and the largest c-rate is the same.), and slow charging labeled ‘Life’), and two applied pressures (4, 40 kgf/cm²). RPTs were conducted at 0, 90, 180, and 270 charge-discharge cycles. During each RPT, the galvanostatic intermittent titration technique (GITT) was initially used to measure cell capacity via a 2.5V CC discharge test.

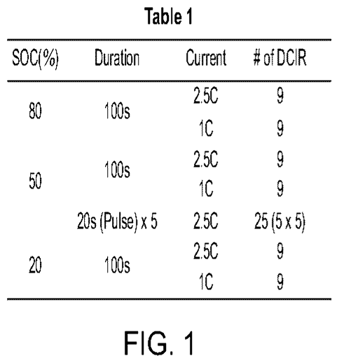

Subsequently, an HPPC test was performed at SOCs of 80%, 50%, and 20%, as detailed in Table 1 shown in FIG. 1. Table 1 is a detailed profile of HPPC tests conducted during each RPT, indicating the number of DCIR measurements taken in each test. A total of 79 DCIR measurements are obtained per RPT. For each SOC, discharging currents of 2.5C and 1C were applied in two distinct pulses, allowing for the calculation of DCIR based on these varying discharge currents. Additionally, at a SOC of 50%, five 20-second pulse tests were performed consecutively. For clarity, the 100-second test is referred to herein as a ‘long pulse test’, and the 20-second test as a ‘short pulse test’ within the HPPC framework.

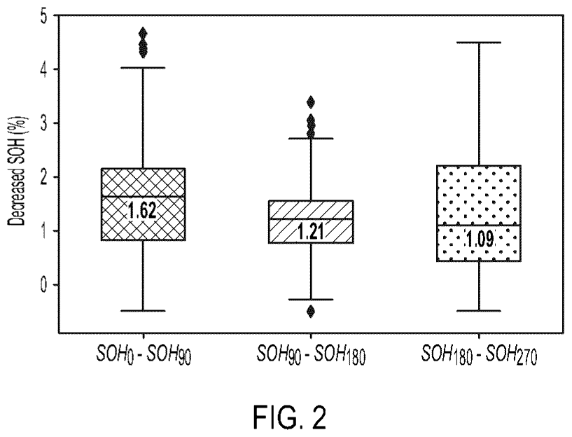

Based on the dataset described, criteria were identified for identifying rapidly degrading cells (classified as ‘Class1’ cells) in the previous study Lee et al., which is briefly revisited herein. Initially, to assess the presence of rapid degradation in the dataset, the degradation percentage for each 90-cycle interval was plotted as shown in FIG. 2, for the 134 cells analyzed. FIG. 2 shows the ratio of SOH degradation for tested cells over each 90-cycle interval. Each boxplot spans from the first quartile (Q1) to the third quartile (Q3), with outliers (below Q1 minus 1.5 times the interquartile range (IQR) or above Q3 plus 1.5 times the IQR, (where IQR=Q3-Q1) represented by dots. The number inside each boxplot represents the average degradation value in each interval.

It is evident that significant degradation typically occurs during the initial 90 cycles, which is largely attributable to the stabilization process, with most cells stabilizing between 90 and 180 cycles. Beyond this point, while many cells exhibit their lowest rate of degradation between 180 and 270 cycles, a noticeable increase in the degradation rate is observed in some cells during the final 90 cycles. This pattern suggests rapid degradation, or a “knee” in the degradation curve, which previous work indicates is more likely to occur under certain operating conditions such as high pressure, extreme temperatures, and fast charging.

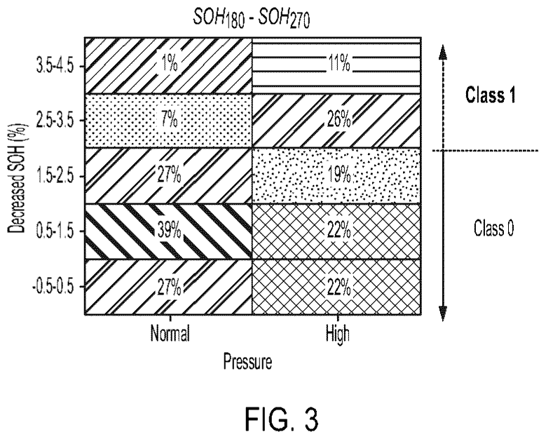

The criterion for identifying Class 1 cells was established based on the degradation rates observed under different pressures during the last 90 cycles. FIG. 3 shows a distribution of SOH degradation rates of cells over the final 90 cycles under normal pressure (4 kgf/cm²) and high pressure (40 kgf/cm²). High-pressure conditions, generally known to accelerate degradation due to various side reactions, significantly affect cell degradation. Data shows that under normal pressure, only about 8% of cells degraded more than 2.5% in the last 90 cycles, whereas under high pressure, this percentage increases dramatically to 37%. Based on this observation, cells degrading more than 2.5% in the last 90 cycles were classified as Class 1 cells, indicative of abrupt capacity fade, while the others were designated as Class 0.

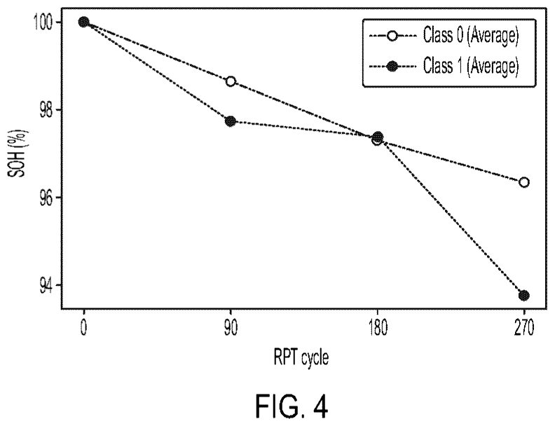

To verify whether this criterion accurately captures the behavior of rapidly degrading cells, as shown in FIG. 4, the average degradation rate of both Class 0 and Class 1 cells at 0, 90, 180 and 270 cycles were analyzed. The results show that Class 0 cells exhibit a nearly linear degradation pattern. In contrast, Class 1 cells display significant acceleration in degradation, particularly in the last 90 cycles, indicating a distinct ‘knee’ in the degradation curve. This differentiation confirms the efficacy of the applied criterion in identifying cells susceptible to rapid degradation.

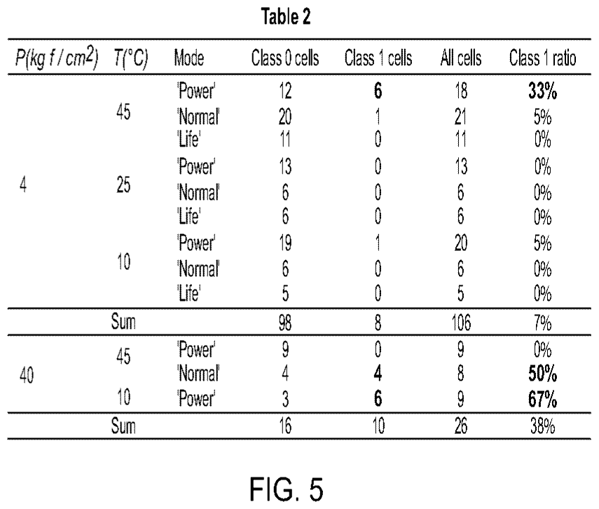

Based on the defined criteria, the distribution of Class 0 and Class 1 cells are examined among a total of 133 cells, analyzing the conditions under which each classification occurred. Table 2 shown in FIG. 5 displays the proportional distribution of Class 0 and Class 1 cells under varying pressures, temperatures, and charging modes, illustrating the prevalence of each class under the various operating conditions. At normal pressure, the majority of cells are classified as Class 0, with only 6 out of 18 cells identified as Class 1 under high-temperature conditions (T_{amb}=45° C.) in Power charging mode. In contrast, at high pressure, all cells at T_{amb}=45° C. in Power mode were Class 0, whereas the other two experimental setups showed a high incidence of Class 1 cells (50% and 67%, respectively). Overall, only 18 out of 134 cells were classified as Class 1. Despite deliberately creating conditions conducive to rapid degradation, the prevalence of rapidly degrading cells under normal operating conditions remains low, consistent with prior knowledge. In a previous study, Class 0 and Class 1 cells were successfully classified with a recall of approximately 0.99 using just the data from the first three cycles. In the current study, our goal is to conduct lifespan regression on these few Class 1 cells, which are even scarcer in real-world conditions, using a simple model to identify the DCIR-based characteristics that make Class 1 cells diagnosable.

### Feature Extraction

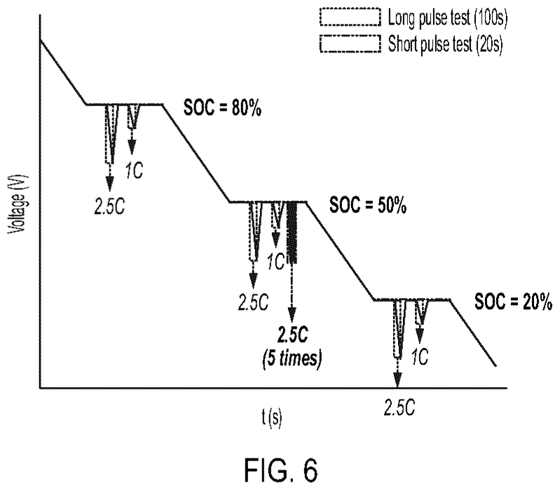

This section outlines the method for deriving multiple resistance terms from the DCIR measurements obtained during the HPPC tests. The HPPC test process is shown in FIG. 6. 2.5C, 1C long pulse tests are conducted in SOC=80, 50, 20%. Additionally, consecutive short pulse tests (20s) are conducted 5 times in SOC=20% after long pulse tests. From SOC=100%, the given cell is discharged with 0.33C until it reaches SOC=0%. Especially, the discharging procedure is paused at SOC 80, 50, 20% to measure DCIR. In these SOCs, CC pulse currents of 2.5C and 1C are applied, then the DCIRs at each SOC are measured based on the voltage change during this period. Specifically, the HPPC includes tests conducted over 100 seconds (long pulse test) and 20 seconds (short pulse test). The division of the measurement timescale post-measurement allows for targeting specific resistance components, each influenced differently by the pulse duration.

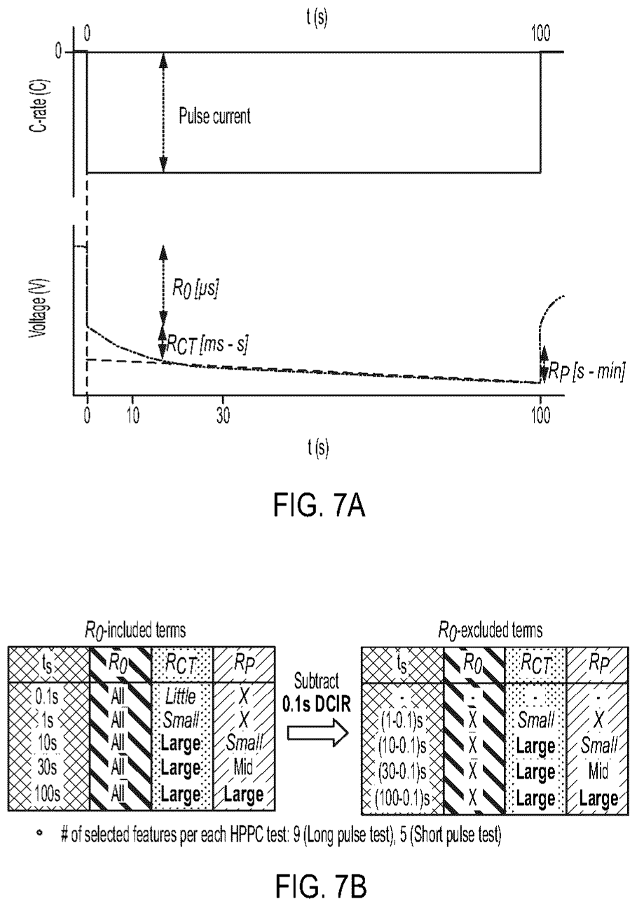

FIGS. 7A and 7B are presented to show the change in voltage when a pulse current is applied and the resistance term associated with each change, and to introduce the feature extracted based on the resistance term. FIG. 7A shows voltage change and time of appearance due to each resistive term when a pulse current is applied for 100 seconds. FIG. 7B shows the timescale of features extracted from each pulse test and the proportion of each resistive term. The short pulse test was only performed for the 20s, so the four terms after 30s were not extracted.

In FIG. 7A, when a pulse current is applied, a rapid voltage drop is observed primarily due to ohmic resistance (Rₒ), which occurs within the first few microseconds and generally represents the most significant drop observed during the entire HPPC test. This is followed by a voltage drop associated with the charge transfer resistance (R_{ct}), which stems from electrochemical reactions at the electrode-electrolyte interface. After several tens of seconds, polarization resistance (Rₚ) becomes apparent, reflecting mass transfer limitations.

With this foundational understanding, nine distinct timescales (tₛ) were established designed to capture Rₒ, R_{ct}, and Rₚ at varying magnitudes, as detailed in FIG. 7B to identify features closely related to SOH regression from these components. The left table shows Rₒ-included terms extracted from the voltage/current difference at 0.1, 1, 10, 30, and 100 seconds from the initial application of the pulse current. To mitigate the predominant impact of Rₒ on the overall voltage drop, four additional DCIR values were calculated by subtracting the 0.1-second DCIR from those measured at 1, 10, 30, and 100 seconds, as shown in the right table. This is 0.1s longer than the actual Rₒ impact time, but the first 0.1s was excluded because the sampling time is set to 0.1s. However, in the rapid degeneracy case, Rat changes significantly in a few seconds, it is expected to be able to extract significant values in terms of Rot and Rₚ even if the insignificant changes in the first 0.1s are excluded.

For the short pulse tests conducted at 50% SOC, five specific DCIR measurements were utilized: direct readings at 0.1, 1, and 10 seconds to include Rₒ effects, and adjusted values for the 1 and 10-second measurements subtracted by the 0.1-second DCIR to focus on longer-term resistance changes (R_{ct}, Rₚ). As a result, 6 long pulse tests (2 times in SOC=80, 50, 20% for 2.5, 1C) and 5 short pulse tests (5 consecutive times in SOC=50%) were performed for each RPT test, resulting in 6×9=54 features from the long pulse tests and 5×5=25 features from the short pulse tests, resulting in 79 DCIR-based features for each RPT to be used for lifespan regression.

### Modeling Framework

This section introduces the EN as the regression model for SOH₂₇₀ predictions based on DCIR measurements and discusses the rationale for selecting EN as the modeling approach. EN is characterized as a linear, sparse model that exploits the linearity between input and output variables. EN is considered sparse because it selectively uses informative input variables through regularization terms, thereby reducing model complexity and mitigating the risk of overfitting.

EN is a linear sparse model that effectively combines features from both LASSO and RIDGE regression to enhance model robustness and feature selection. It is mathematically represented as follows:

$${min}_{w} {‖ y - Xw ‖}_{2}^{2} + a ( {l}_{1} {‖ w ‖}_{1} + \frac{1 - {l}_{1}}{2} {‖ w ‖}_{2}^{2} )$$

In this formula, y represents the dependent variable vector, X is the matrix of input variables, w are the coefficients to be optimized, a is a hyperparameter that controls the overall strength of the regularization, and l₁ balances the LASSO (l₁-norm) and RIDGE (l₂-norm) components.

The LASSO component, which uses the l₁-norm, zeros out the coefficients of less significant input variables, promoting model sparsity and emphasizing key features. The RIDGE component, utilizing the l₂-norm, addresses over-fitting by reducing multicollinearity among input variables. By adjusting l₁ within the range of 0 to 1, the model can vary from being purely RIDGE (when l₁=0) to purely LASSO (when l₁=1). This flexibility allows the model to leverage the strengths of both methods, depending on the data and desired outcomes. By increasing l₁, more coefficients are driven to zero, simplifying the model, whereas the l₂-norm component helps balance the coefficients to reduce the chances of overfitting, which is crucial when dealing with multicollinear or numerous predictors. The tuning of EN involves adjusting the hyperparameters a and l₁. The optimal settings for these parameters are typically found through a process of trial and error, aiming to strike the best balance between model complexity and prediction accuracy. If EN is tuned correctly, it allows for an analysis of which input variables are most influential by observing which coefficients remain non-zero across various settings of l₁, providing insights into the variables that most significantly impact the dependent variable.

Based on the characteristics of ENs, the model was chosen for the study for several reasons. First, a linear model was opted for due to the practical scarcity of Class 1 cells and the need for a model that an on-board BMS can efficiently utilize. Resistance variables are expected to correlate more directly with SOH₂₇₀ than VIT variables, making them more suitable for lifespan prediction in a linear modeling context. For the feature selection aspect of the model, 79 DCIRs were utilized as input variables, as described above. These DCIR measurements include various resistance terms such as Rₒ, R_{ct}, and Rₚ. Using a dense model with all these input variables could lead to overfitting, complicating the interpretation of which DCIRs are most relevant to the battery's lifetime characteristics. In contrast, a sparse model not only mitigates the risk of overfitting but also enhances model explainability by highlighting key input variables through nonzero-weighted coefficients. The sparse nature of the EN model is particularly valuable because it enables analysis of the significance of the measured resistance terms across different timescales and SOC, enhancing the model's relevance and applicability to real-world EV settings. This approach supports a deeper understanding of which aspects of the DCIR measurements are most predictive SOH₂₇₀, making it possible to interpret how the model might be implemented in actual EV operations. The results and implications of the SOH₂₇₀ regression model, developed with these insights, are discussed further below.

### Results of Experiments

This section describes the results of the SOH₂₇₀ linear regression model based on DCIR for Class 1 cells, and examines the input-output correlations and the patterns of highly correlated DCIR terms under conditions of rapid degradation. This analysis aims to elucidate further why DCIR serves as a robust input variable in cases of rapid degradation during EV operation.

### Regression Results

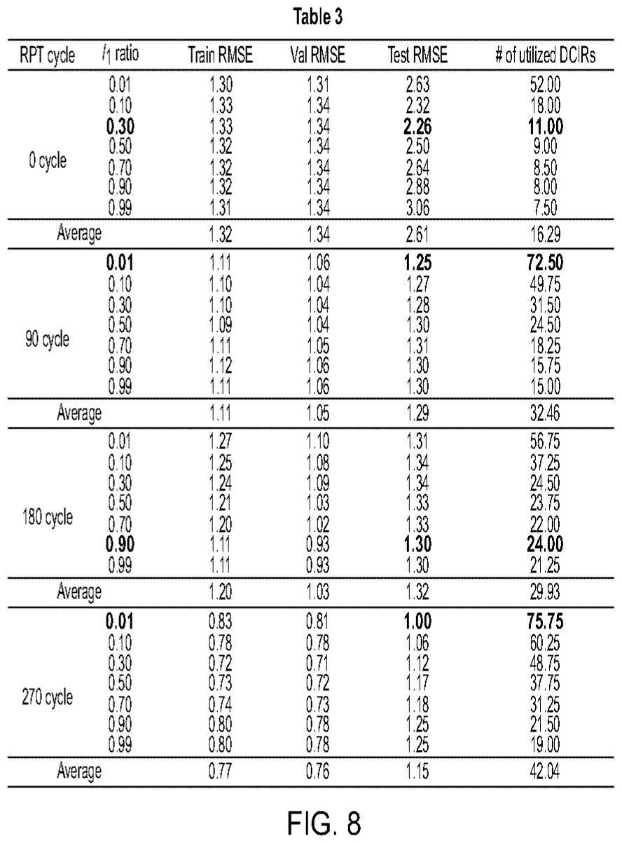

Table 3 shown in FIG. 8 depicts the average regression performance of the SOH₂₇₀ linear regression model across five random seeds as a function of the l₁-ratio, utilizing RHI-based DCIR measurements in Class 1 cells from each RPT cycle.

A notable variation in test set regression performance is observed at the RPT=0 cycle as a function of the l₁-ratio. In contrast, for RPT=90, 180, and 270 cycles, the performance remains relatively consistent regardless of the l₁-ratio, with these later cycles generally outperforming the initial RPT=0 cycle in test set results.

From these results, the instances with the lowest test set RMSE are identified and analyzed in conjunction with the number of variables (influenced by the l₁-ratio) employed. For example, using DCIRs from the 0 cycle results in a test set RMSE for SOH₂₇₀ of approximately 2.26%, with an average of only 11.0 DCIR variables (out of 79) being used as valid inputs. Despite a significantly smaller l₁-ratio being optimal (l₁=0.9) in the 180 cycle case compared to the 0 cycle case, an average of 24 DCIR variables are utilized in the 180 cycle case. This suggests that the EN model did not effectively capture the relevant DCIR values in the initial 0 cycle scenario, indicating a need for further investigation into the predictive power of early-cycle DCIR measurements.

On the other hand, using DCIRs from the 90, 180, and 270 cycle points significantly improved SOH₂₇₀ prediction performance across all datasets, particularly achieving an average error of only 1.25%, 1.30%, and 1.00% in the test set, respectively. Notably, an average of 72.50, 24.00, and 75.75 DCIRs were assigned nonzero weights by the EN in each respective RPT cycle for the best-case scenarios. This is consistent with the variable analysis results, which show a large number of DCIRs demonstrating linearity and monotonicity with SOH₂₇₀ following the cycling process.

In terms of overall regression performance across all l₁-ratios and considering the selected input variables, the models based on 90, 180, and 270-cycle DCIRs significantly outperformed the 0-cycle model, improving prediction accuracy by about 50% or more while utilizing on average twice as many DCIR values. This highlights the increased predictive power and relevance of DCIR measurements taken at later cycles in accurately estimating the state of health of the battery.

Compared to the two-dimensional convolutional neural network (2D CNN) model that used VIT data from Lee et al., the model using the first 90 cycles of SOH₂₇₀ data yielded an average test set RMSE of 7.52% without oversampling and 1.73% with oversampling. In contrast, the model utilizing only the DCIR measured at 90 cycles as an input variable demonstrated superior performance, achieving an average test set RMSE of 1.29%, which represents a 25.4% improvement compared with the case with oversampling. Additionally, the simpler structure of this model highlights its feasibility for integration into an on-board BMS, unlike the more complex 2D CNN model. These results underscore that while Class 1 cells, which exhibit rapid and non-linear degradation in SOH, typically require sophisticated modeling approaches, especially when data availability is limited, it is possible to construct effective SOH₂₇₀ prediction models for these cells by identifying variables with high linear and monotonic correlations to SOH₂₇₀. This approach allows for the development of satisfactory prediction models using a minimal number of cells, simplifying the modeling process and enhancing its applicability in real-world scenarios.

### Correlation Analysis

This section provides a detailed analysis of the value of DCIR as an input variable for cells undergoing abrupt degradation, and analyzes the linear correlations between DCIRs from each RPT cycle and SOH₂₇₀ using Pearson and Spearman correlation coefficients. Subsequently, this section compares the patterns of DCIRs that exhibit high correlations with SOH₂₇₀ across both classes of cells and proposes a method for diagnosing abrupt capacity fade based on changes in DCIR patterns.

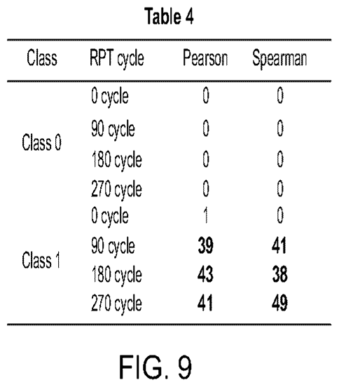

Table 4 shown in FIG. 9 illustrates the correlations between SOH₂₇₀ and the DCIR measured at each 90-cycle interval for both Class 0 and Class 1 cells. Pearson and Spearman correlations are computed to assess the linearity and monotonicity of the DCIRs with SOH₂₇₀. Table 4 illustrates the number of DCIRs exhibiting strong linear (Pearson) and monotonic (Spearman) correlations with SOH₂₇₀, with coefficients exceeding 0.5. For Class 0 cells, DCIRs consistently show negligible linearity or monotonicity with SOH₂₇₀ regardless of the RPT cycle, suggesting that constructing robust linear regression models solely based on DCIR measurements for predicting SOH₂₇₀ in these cells would be challenging. Conversely, for Class 1 cells, while DCIRs measured during the initial 0-cycle RPT (before cycling begins) show little significance for lifespan prediction, DCIRs taken after 90, 180, and 270 cycles demonstrate strong linearity and monotonicity with SOH₂₇₀. Over 50% of the 79 measured DCIRs are identified as significant features (Pearson or Spearman coefficient >0.5). This substantial correlation explains the effective performance of the DCIR-based EN model in predicting SOH₂₇₀ for Class 1 cells, highlighting the importance of DCIR as a predictor in scenarios involving rapid degradation.

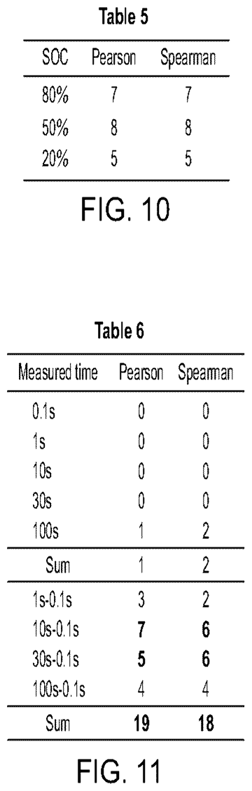

To further dissect the significance of DCIRs, the top 20 DCIRs were identified, which are defined by having both Pearson and Spearman coefficients above 0.5 after cycling (hereafter referred to as top-20 DCIRs). Initially, the state of charge (SOC) distribution of these top-20 DCIRs was analyzed, as displayed in Table 5 shown in FIG. 10. The SOCs at which these significant DCIRs were measured showed little variation, indicating that differences in SOC do not markedly influence the identification of significant DCIRs. This observation aligns with existing knowledge that the most critical DCIR term in Class 1 cells, Rat, does not vary significantly within the SOC range of 20 to 80%.

In terms of measurement timescale, 19 out of the top 20 DCIRs are those measured beyond the initial 0.1 seconds (Pearson). Specifically, among those excluding the 0.1-second DCIR measurement, 7 had a total measurement time of 10 seconds, and 5 spanned 30 seconds. Similarly, based on Spearman coefficients, 18 of the top 20 DCIRs excluded the initial 0.1-second measurement, with 6 each having total measurement times of 10 and 30 seconds.

This analysis supports the understanding that Rₒ is not particularly relevant for predicting the SOH of Class 1 cells. Moreover, the total times of 10 and 30 seconds, minus the initial 0.1 seconds, are identified as the timescales where the most informative DCIRs are measured. Notably, the 30-second measurement, which is not included in the short pulse test (SOC=50%) and occurs only six times per RPT, is represented five times among the top 20 variables by Pearson's coefficient and all six times by Spearman's coefficient. This indicates that measuring DCIR over a 30-second period may be particularly valuable as it potentially captures both R_{ct} and Rₚ, providing a more comprehensive insight into the resistances affecting the battery's health.

### Analysis of DCIR Patterns in Various Operating Conditions

This section analyzes DCIRs measured in different RPT cycles under various operating conditions, and compares the average DCIR values for corresponding cells, discussing their consistency with insights from previous research and their implications for understanding LIB capacity degradation. Table 6 shown in FIG. 11 displays top-20 DCIRs by measurement duration, where values are adjusted by subtracting the initial 0.1s DCIR to isolate contributions beyond ohmic resistance. The most relevant timescales for the lifetime characteristics of Class 1 cells are those measured at 30-0.1 and 10-0.1 seconds. Generally, selecting the appropriate measurement timescale for DCIR is crucial to harness this data for battery diagnostics effectively.

This analysis focuses on the DCIR patterns at 30-0.1 and 10-0.1 seconds under various operating conditions, and explores how these specific timescales correlate with SOH₂₇₀ and assess their utility in diagnosing rapid degradation. Additionally, data from short pulse tests at 50% SOC have been excluded, as utilizing five consecutive short pulse tests may not be feasible in real EV scenarios, and these measurements have shown poor correlation with SOH₂₇₀.

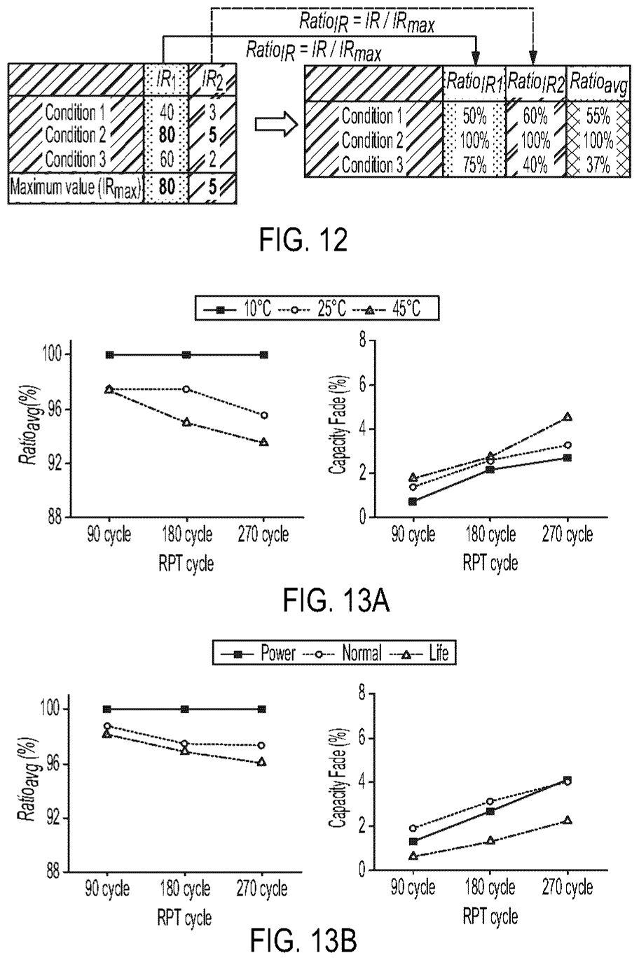

To address the variability of DCIR values across different operating conditions and measurement timescales, a normalization term, Ratio_{avg} was introduced. This metric helps to fairly compare the magnitude of average DCIR values under different conditions. FIG. 12 illustrates the computation of Ratio_{avg}. For instance, if analyzing two IR values across three operating conditions (using 12 DCIR values measured at timescales of 30-0.1 and 10-0.1 seconds in a real case), determine the maximum value among each set of DCIRs is first determined and then each DCIR as a ratio of this maximum value is calculated in each operating condition (Ratio_{IR1}, Ratio_{IR2}). The average of these ratios (Ratio_{IR}) across all conditions is then calculated and presented as Ratio avg, which serves as a standardized measure to compare DCIRs across different operating conditions.

Using Ratio avg as a benchmark, the patterns of DCIR in relation to operating conditions and their implications for capacity degradation, particularly in scenarios with normal pressure, are discussed below. This discussion pertains to the operating conditions under which some Class 1 cells are observed in the normal pressure scenario, examining how their resistance profiles diverge from typical patterns, and discusses how DCIR patterns shift under high-pressure conditions where there is a higher prevalence of Class 1 cells. These patterns could potentially serve as early indicators of abrupt capacity fade. This discussion helps clarify why Class 1 cells exhibit a highly linear and monotonic relationship with SOH₂₇₀, emphasizing the diagnostic potential of DCIR in predicting rapid degradation events in lithium-ion batteries.

### Normal Pressure Case

FIGS. 13A and 13B show a comparison of Ratio avg and average SOH decrease in normal pressure cells across different operating conditions, by ambient temperature (T_{amb}) in FIG. 13A, and by charging modes in FIG. 13B. FIGS. 13A and 13B show the Ratio_{avg} alongside the amount of capacity fade (100-SOH(%)) at each RPT cycle for the normal pressure scenario, where there are few Class 1 cells. FIGS. 13A and 13B also highlight the primary operating condition, T_{amb}, and changes in charging mode to discuss general patterns based on operating conditions.

Starting with T_{amb}, it is observed that resistance rise and capacity fade exhibit almost opposite trends. Typically, resistance increases as T_{amb} decreases due to reduced ionic mobility within the battery, while capacity fade intensifies as T_{amb} decreases primarily because of more pronounced lithium plating. Conversely, capacity fade associated with solid-electrolyte interface (SEI) formation escalates as T_{amb} increases. This complex interaction makes it challenging to discern a direct relationship between resistance changes and capacity fade based purely on T_{amb}. Notably, in the dataset, there was minimal abrupt capacity fade due to lithium plating at T_{amb}=10° C. within the normal pressure group. However, most of the Class 1 cells (6 out of 8 in normal pressure scenarios) experienced significant capacity fade at T_{amb}=45° C., indicating that this temperature setting contributes to the highest average capacity fade in the last 90 cycles. This observation aligns with the idea that SEI formation, exacerbated at higher temperatures, primarily occurs during the early cycles. In the initial 90 cycles, there is a substantial difference in Ratio_{avg} between T_{amb}=10° C. and T_{amb}=25° C.; however, the difference between T_{amb}=25° C. and T_{amb}=45° C. is negligible. As cycling progresses, the disparity in Ratio avg between T_{amb}=25° C. and T_{amb}=45° C. expands, suggesting a deviation from typical patterns at T_{amb}=45° C. in the initial 90 cycles, which could signal potential further capacity degradation.

Regarding charging mode, the relationship between resistance rise and capacity fade does not exhibit the clear opposition observed with T_{amb}. Resistance increases are more pronounced in ‘Power’ mode compared to ‘Normal’ and ‘Life’ modes, indicating that the impact of charging mode on resistance is considerably less than that of T_{amb}. For capacity fade, fast charging modes (‘Normal’ and ‘Power’) display more degradation than the ‘Life’ mode. Specifically, during the first 180 cycles, ‘Normal’ mode cells show more capacity fade, but in the last 90 cycles, ‘Power’ mode cells exhibit greater degradation, potentially indicating imminent rapid degradation. This pattern suggests that ‘Power’ mode cells, which demonstrate a higher Ratio_{avg} in terms of resistance during the 0-180 cycles, are already displaying early signs of future abrupt capacity fade.

This analysis examines the changes in resistance patterns and their correlation with capacity fade under specific conditions: Condition 1, ‘Power’ mode at T_{amb}=45° C., and Condition 2, ‘Normal’ mode at T_{amb}=10° C. These conditions represent typical operational scenarios observed in the normal and high-pressure cases, where Class 1 cells are predominantly found. Each scenario is compared to a high-pressure case in ‘Power’ mode at T_{amb}=45° C., where Class 1 cells are absent, to analyze how resistance changes under similar conditions and its implications for capacity fade.

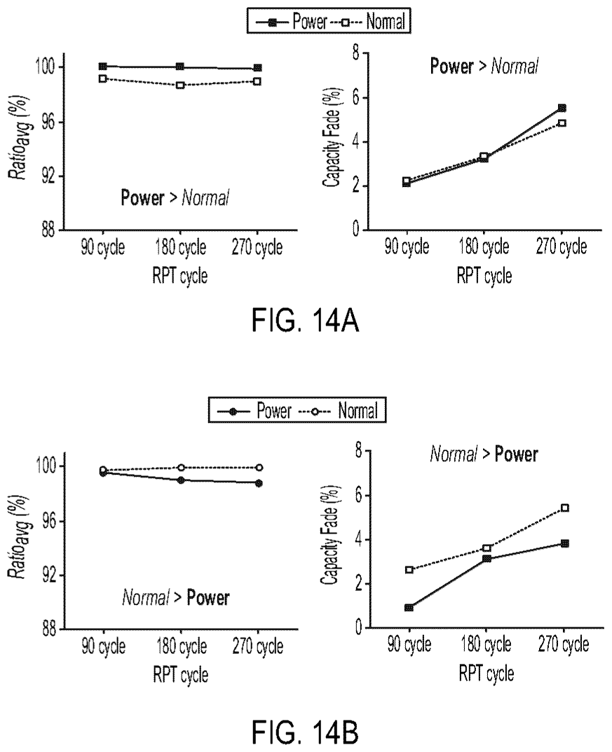

The effects of T_{amb} under each pressure setting are discussed. FIGS. 14A and 14B display a comparison of Ratio_{avg} and average SOH decrease under pressure variations, focusing on ‘Power’ mode cells at T_{amb}=10° C. and T_{amb}=45° C. This comparison is based on a limited set of operating conditions in high-pressure scenarios. FIG. 14A illustrates the normal pressure scenario, indicating that higher resistance at lower temperatures (T_{amb}=10° C.) is attributed to reduced ionic mobility, a natural cycling phenomenon unrelated to capacity fade caused by side reactions. Consequently, the Ratio avg is 2.3˜5.9% higher throughout the cycles at T_{amb}=10° C., while capacity fade shows a reverse trend.

Conversely, FIG. 14B shows that for the high-pressure case both resistance rise and capacity fade are higher at T_{amb}=10° C. Notably, the gap in Ratio_{avg} between T_{amb}=10° C. and T_{amb}=45° C. has significantly widened to 3.6˜8.6%, indicating that this divergence is likely due to acute side reactions rather than just operational conditions. The marked increase in DCIR during cycles 0 to 180, coupled with significant capacity fade in cycles 180 to 270, suggests that DCIR is a valuable input for diagnosing potential abrupt capacity fades in the future rather than solely estimating current cycle SOH.

### High-Pressure Case-Charging Mode Effect

This section explores the effects of charging mode on cell performance under different pressure conditions. FIGS. 14A and 14B show the Ratio avg and the average decrease in SOH in response to pressure changes, focusing on cells in ‘Power’ and ‘Normal’ modes at T_{amb}=45° C. FIG. 14A displays the normal pressure case, while FIG. 14B illustrates the high-pressure scenario, taking into account the limited operating conditions in high-pressure scenarios.

Under normal pressure, ‘Power’ mode cells, which typically operate at a higher c-rate across a larger SOC range, exhibit a greater resistance rise compared to ‘Normal’ mode cells. However, the difference in capacity fade between the two modes is not significant. This suggests that while the ‘Power’ mode may induce higher resistance due to increased stress on the battery, it does not necessarily translate into a correspondingly higher rate of capacity degradation.

In the high-pressure environment, a notable reversal in the DCIR pattern occurs starting from the 90-cycle mark. This shift could indicate abrupt side reactions that deviate from the typical pattern observed in ‘Normal’ mode cells prior to the 90-cycle mark, leading to significantly greater capacity fade in these cells. Notably, the capacity fade in ‘Normal’ mode cells shows a temporary stabilization between the 90 to 180 cycles, followed by rapid degradation in the 180 to 270 cycle period. This pattern suggests that the predictability of DCIR remains reliable, as the resistance in ‘Normal’ mode has been consistently higher than in ‘Power’ mode since the beginning of this phase. These observations highlight the complex interplay between charging mode, pressure conditions, and thermal environment in influencing the electrochemical behavior and degradation patterns of lithium-ion cells. The differential impact on resistance and capacity fade underscores the importance of considering these factors when assessing battery health and longevity in practical applications.

This analysis explores how the DCIR measurements of Class 1 cells—particularly those terms involving R_{ct}—displayed before the last cycle exhibit a high degree of linearity and monotonicity with SOH₂₇₀. In scenarios dominated by Class 0 cells, such as the normal pressure case, the typical patterns of resistance rise are analyzed according to operating conditions and noted that these are generally not closely related to capacity fade. However, for Class 1 cells, deviations from these typical patterns were observed, suggesting that such changes may be indicative of resistance increases due to abrupt side reactions.

Particularly notable are the increases in the DCIR gap or reversals in the pattern itself, depending on the operating condition, which are strongly associated with rapid degradation. Since these changes manifest before actual capacity degradation becomes apparent, it is demonstrated that it is feasible to diagnose rapidly degrading cells and predict their life characteristics using only DCIR measurements. This approach underscores the predictive power of DCIR as a tool for early detection of potential failures and estimation of battery longevity under varying operational stresses.

### Discussion of Results of Experiments

Thus, the present systems and methods advantageously deploy a lifespan regression model for rapidly degrading cells (Class 1 cells) using DCIR, a metric that can be easily measured during the charging and discharging processes of battery cells in EVs and other applications. Given the rarity of rapidly degrading cells during typical EV operation and the impracticality of equipping on-board BMS with complex neural network-based models, the present systems and methods opt for a simpler regression model using an EN. This approach demonstrates superior performance compared to neural network models using VIT data, with numerous DCIR variables playing a significant role.

The present disclosure focuses on the linearity and monotonicity between DCIR measurements and the last cycle state of health (SOH₂₇₀). Notably, the charge transfer resistance (R_{ct})-based terms showed very high linearity and monotonicity with SOH₂₇₀ for Class 1 cells, underscoring the importance of excluding ohmic resistance (Rₒ) when diagnosing rapidly degrading cells and predicting their lifespan.

The present disclosure also examines the variations in Rot-based terms across different RPT cycles and correlates these changes with capacity under various operating conditions. For Class 0 cells (slowly degrading), there was no discernible relationship between resistance increase and capacity fade over time, and it was challenging to distinguish resistance changes due to operational conditions from those due to side reactions. However, Class 1 cells (rapidly degrading) exhibited strong correlations between resistance increase and capacity fade, confirming the potential to diagnose rapid degradation and predict future lifespan based on deviations from typical patterns under specific operating conditions.

### Method for Diagnosing Rapidly Degrading Battery Cells Using DCIR

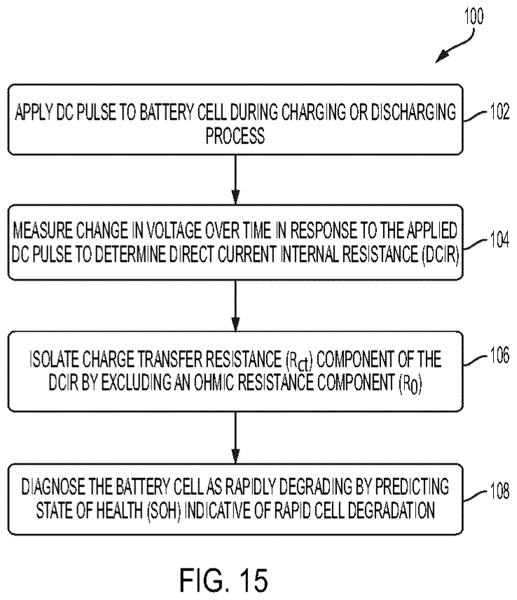

FIG. 15 is a flow chart showing a method 100 for diagnosing rapidly degrading battery cells using DCIR, in accordance with an aspect of the present disclosure. The method 100 may be performed for one or more battery cells in a stationary battery system (such as a battery pack or module or a battery energy storage system (BESS) including battery racks), an electric vehicle (e.g., an electric car, truck, boat, or airplane) or other electronic device (e.g., a cellphone or a laptop). The method 100 may be a computer-implemented method that is performed by a controller (e.g., computing device).

At step 102, a direct current (DC) pulse may be applied to a battery cell during at least one of a charging process or a discharging process. For example, a DC pulse may be applied to a battery cell during a discharging process by performing an HPPC test. The HPPC test may include tests conducted over 100 seconds (long pulse test) and 20 seconds (short pulse test). An example of the HPPC test process is shown in FIG. 6, where discharging currents of 2.5C and 1C are applied in two distinct pulses at different SOC including 80%, 50%, and 20% (see also Table 1 as described with respect to FIG. 1). In some cases, the applied discharging currents may comprise two or more of 0.1, 0.2, 0.3, 0.4, 0.5, 0.6, 0.7, 0.8, 0.9, 1.0, 1.5, 2.0, 2.5, 3.0 C, however the present disclosure is not limited thereto. In some cases, the pulse is applied at a SOC comprising 5, 10, 15, 20, 25, 30, 35, 40, 45, 50, 55, 60, 65, 70, 75, 80, 85, 90, or 100%, however the present disclosure is not limited thereto. In some cases, at a SOC of 50%, five 20-second pulse tests may be performed consecutively. In some case, the DC pulse may be applied at or after 0, 90, 180, or 270 charge-discharge cycles, although the present disclosure is not limited thereto.

At step 104, a change in voltage over time (dV/dt) is measured in response to the applied DC pulse to determine DCIR. For example, FIG. 7A shows the change in voltage over time and time of appearance due to each resistance component when a long pulse current is applied for 100 seconds. When a pulse current is applied, a rapid voltage drop is observed primarily due to ohmic resistance (Rₒ), which occurs within the first few microseconds (e.g., <0.1 seconds) and generally represents the most significant drop observed during the entire HPPC test. This rapid voltage drop is followed by a voltage drop associated with the charge transfer resistance (R_{ct}), which stems from electrochemical reactions at the electrode-electrolyte interface. After several tens of seconds, polarization resistance (Rₚ) becomes apparent, which reflects mass transfer limitations.

At step 106, a charge transfer resistance (R_{ct}) component of the DCIR may be isolated by excluding an ohmic resistance (Rₒ) component from the DCIR. For example, FIG. 7B shows the resistance components extracted in various timescales of each pulse test, and the proportion of each resistance component. Five distinct timescales (tₛ) are established to capture Rₒ, R_{ct}, and Rₚ at varying magnitudes: 0.1, 1, 10, 30, and 100 seconds. To mitigate the predominant impact of Rₒ on the overall voltage drop, additional DCIR values are determined by subtracting the DCIR value measured at 0.1 seconds (representing Rₒ) from the DCIR value measured at 1, 10, 30, and 100 seconds (representing R_{ct} and Rₚ).

At step 108, the battery cell may be diagnosed as rapidly degrading (e.g., “Class 1” cell) based on the R_{ct} component by predicting a SOH of the battery cell indicative of rapid cell degradation. For example, the R_{ct} component may be input as a feature into a classifier to predict the SOH of the battery cell at 180 charge-discharge cycles and 270 charge-discharge cycles.

The battery cell may be diagnosed as rapidly degrading when a difference of the predicted SOH at 270 charge-discharge cycles and the predicted SOH at 180 charge-discharge cycles is at least about 2.5%. While many cells exhibit their lowest rate of degradation between 180 and 270 cycles, a noticeable increase in the degradation rate is observed in some cells during the final 90 cycles. For example, as described with respect to FIG. 4, cells that are not rapidly degrading (e.g. “Class 0” cells) exhibit a nearly linear degradation pattern. In contrast, cells that are rapidly degrading (e.g., “Class 1” cells) display significant acceleration in degradation, particularly in the last 90 cycles, indicating a distinct ‘knee’ in the degradation curve.

In some cases, the classifier is a linear regression model that employs elastic net (EN) regression, which may be characterized as a linear, sparse model that exploits the linearity between input and output variables. For example, see the description with respect to FIGS. 8-11. In some cases, the classifier is a machine-learning based model such as a neural network model, a support vector machine (SVM), a random forest classifier, a gradient boosting model, or other supervised learning algorithm. These models may be trained on historical battery cycling data to learn patterns between Rot and subsequent battery degradation between SOH₁₈₀ SOH₂₇₀. The selection of classifier type may depend on factors such as the size of available training data, computational resources of the battery management system, and required prediction accuracy.

### System for Diagnosing Rapidly Degrading Battery Cells Using DCIR

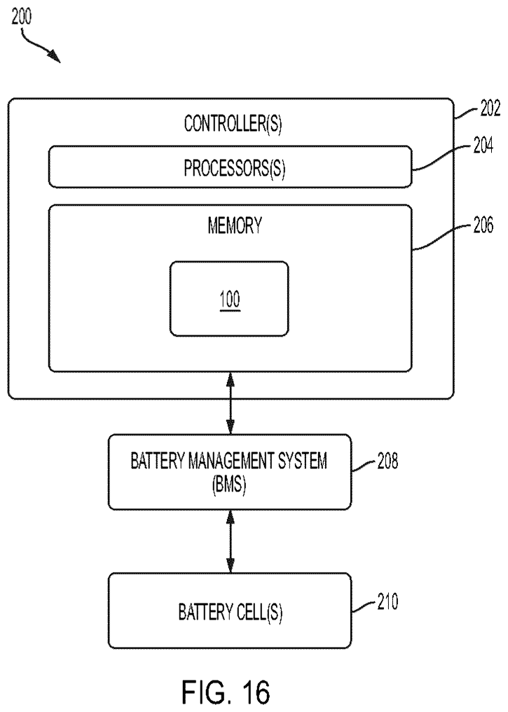

FIG. 16 is a diagram showing a system 200 for diagnosing rapidly degrading battery cells using DCIR, in accordance with an aspect of the present disclosure. The system 200 may include a controller 202 which may implement the method 100 described with respect to FIG. 15. In some cases, the controller 202 may be integrated with a BMS 208 that manages the charging/discharging and monitoring of one or more battery cells 210. In some cases, the controller 202 and the BMS 208 are a single device. In some cases, the controller 202 may include the BMS 208, or vice versa. In some cases, the controller 202 may be external to the BMS 208 and may communicate with the BMS 208 via a circuit, a wired connection or a wireless connection.

The controller 202 may include one or more processors 204 (i.e., processing modules) configured to execute program instructions maintained on a memory 206 (i.e., memory modules). In this regard, the one or more processors 204 of controller 202 may execute any of the various models, methods, processes, steps, or algorithms described throughout the present disclosure, for example, the steps 102-108 of the method 100 described with respect to FIG. 15. For example, the controller 202 may apply a DC pulse to the battery cell(s) 210 by directing the BMS 208 to apply the DC pulse (e.g., using a current regulator to set a constant current). The controller 202 may measure a change in voltage over time (dV/dt) by directing the BMS 208 to measure the change in voltage over time (e.g., using a voltage sensor) and determine DCIR. The controller 202 may isolate the Ret component of the DCIR and exclude the ohmic resistance (Rₒ) component, for example, by subtracting DCIR determined at the 0.1 second timescale (Rₒ) from the DCIR determined at later timescales such as 10 seconds and 30 seconds (R_{ct} and Rₚ). The controller 202 may diagnose the battery cell 210 as rapidly degrading (e.g., “Class 1” cell) based on the R_{ct} component by predicting a SOH of the battery cell indicative of rapid cell degradation, for example, by inputting the R_{ct} component as a feature into a classifier. Further, the controller 202 may be configured to receive data including, but not limited to voltage over time, current over time, SOC, SOH, cell temperature, cell pressure, c-rate, charging mode, charge-discharge cycle count, power output, charging duration, discharging duration, and pulse duration data.

The controller 202 (i.e., computing device) may comprise a desktop computer, mainframe computer system, workstation, server computer, embedded system, image computer, parallel processor, mobile device, tablet, headset, wearable computer, or any other computer system (e.g., networked computer). The one or more processors 204 of the controller 202 may include any processing element known in the art. In this sense, the one or more processors 204 may include any microprocessor-type device configured to execute algorithms and/or instructions, for example, application specific integrated circuit (ASIC), field programmable gate array (FPGA), parallel processor, graphics processing unit (GPU), central processing unit (CPU), microcontroller units (MCUs), digital signal processors (DSPs), system-on-chip (SoC) processors, programmable logic controllers (PLCs), a logical circuit, an electronic processor, or other chipsets. It is further recognized that the term “processor” may be broadly defined to encompass any device having one or more processing elements, which execute program instructions from a non-transitory memory 206. Further, the steps described throughout the present disclosure may be performed by a single controller 202 or, alternatively, multiple controllers. For example, the controller 202 and the BMS 208 may be the same controller or multiple controllers. Additionally, the controller 202 may include one or more controllers housed in a common housing or within multiple housings. In this way, any controller or combination of controllers may be separately packaged as a module suitable for integration into the system 200.

The memory 206 may include any storage medium known in the art suitable for storing program instructions executable by the associated one or more processors 204. For example, the memory 206 may include a non-transitory memory medium. By way of another example, the memory 206 may include, but is not limited to, a read-only memory, a random access memory, a magnetic or optical memory device (e.g., disk), a magnetic tape, a solid state drive, etc. It is further noted that memory 206 may be housed in a common controller housing with the processor(s) 204. In some cases, the memory 206 may be located remotely with respect to the physical location of the processors 204 and controller 202. For instance, the one or more processors 204 of controller 202 may access a remote memory (e.g., server or cloud), accessible through a network (e.g., internet, intranet and the like).

The systems and/or methods of the present disclosure may be implemented as computer programs stored in the memory 206. Any of the data, information, models, metrics, figures, statistics, inputs, outputs, values, variables or parameters described in the present disclosure may be stored in the memory 206. A computer program (also known as a program, program instructions, software, software application, script, or code) can be written in any form of programming language, including compiled or interpreted languages, declarative or procedural languages, and it can be deployed in any form, including as a stand-alone program or as a module, component, subroutine, object, or other unit suitable for use in a computing environment. A computer program may, but need not, correspond to a file in a file system. A program can be stored in a portion of a file that holds other programs or data (e.g., one or more scripts stored in a markup language document), in a single file dedicated to the program in question, or in multiple coordinated files (e.g., files that store one or more modules, sub-programs, or portions of code). A computer program can be deployed to be executed on one controller or on multiple controllers that are located at one site or distributed across multiple sites and interconnected by a communication network.

To provide for interaction with a user, embodiments of the subject matter described in this specification may be displayed on a user interface (UI), such as a display device, e.g., a CRT (cathode ray tube), LCD (liquid crystal display), LED (light-emitting diode), OLED (organic light-emitting diode), micro-LED, mini-LED, plasma, DLP (Digital Light Processing), QLED (Quantum dot LED), or e-ink monitor for displaying information to the user. An input device such as a keyboard and/or a pointing device (e.g., a mouse, touchpad, touchscreen, capacitive touchscreen, resistive touchscreen, stylus, digital pen, game controller, joypad, joystick, gamepad, remote control, gesture control device, eye-tracking device, facial recognition system, and/or a trackball), may be used to provide input to the computer. Input may also be provided through wearable devices such as smart glasses, smart watches, VR and/or AR goggles, rings, or other body-worn sensors. While visual or graphical user interfaces are described here, the disclosure contemplates screen readers or voice-controlled systems and other auditory systems as user interfaces, including natural language processing systems, voice recognition systems, and/or text-to-speech systems. The disclosure also contemplates multimodal interaction combining two or more input methods simultaneously or sequentially, such as touch input combined with gesture control.

In some cases, a battery type (i.e., chemistry) of the battery cell(s) 210 may be one or more of the following: lithium ion, lithium nickel manganese cobalt (NMC), lithium iron phosphate (LFP), lithium sulfur (Li—S), solid state, sodium ion (e.g., sodium sulfur (NaS), sodium nickel chloride), potassium ion, aluminum ion, lead-acid, silicon anode, or combinations thereof, although the present disclosure is not limited thereto. Other battery types may include lithium titanate (LTO), magnesium ion, calcium ion, organic radical batteries, and solid polymer electrolyte batteries.

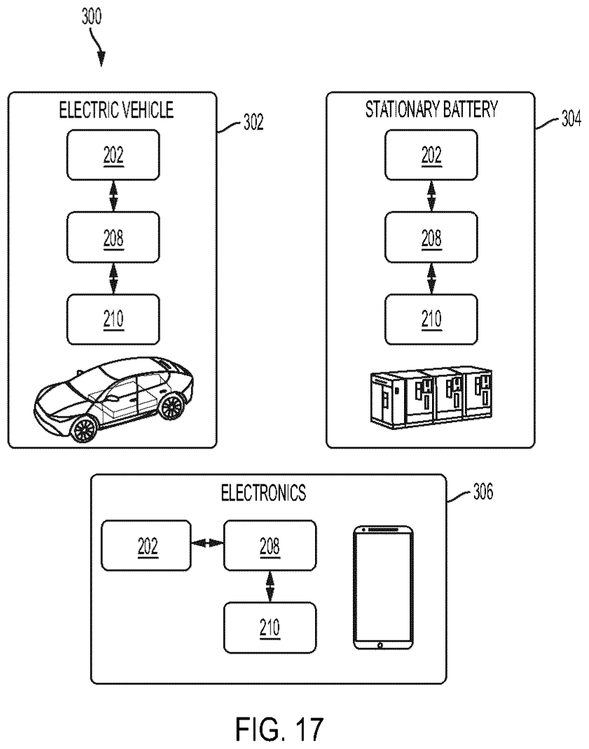

FIG. 17 is a diagram showing the integration 300 of the system 200 in various applications, in accordance with an aspect of the present disclosure.

In some cases, the system 200 may be integrated with an electric vehicle 302. The electric vehicle 302 may be, for example, a car, truck, semi-truck, van, bus, train, subway, trolley, tram, forklift, scooter, bicycle, motorcycle, watercraft, boat, ship, ferry, aircraft, airplane, helicopter, drone, robot, construction vehicle, or other electrically-powered vehicle. For example, when the electric vehicle 302 is a car, the method 100 may be implemented during a discharging process, such as while driving or when supplying electricity to a grid using a vehicle-to-grid (V2G) system, or during a charging process.

In some cases, the system 200 may be integrated with a stationary battery system 304, such as a battery energy storage system (BESS). The BESS may comprise a plurality of battery racks, which in turn respectively comprise a plurality of battery modules or packs. A suitable exemplary battery rack may be, for example, the TR1300 (Model ERT5422CN201) manufactured by LG Energy Solution.

In some cases, the system 200 may be integrated with an electronic device 306, such as a cellphone, laptop, tablet, smartwatch, fitness tracker, smart glasses, augmented reality headset, virtual reality headset, gaming console, portable gaming device, digital camera, video camera, smart speaker, smart display, smart home device, wireless earbud, wireless headphone, power tool, smart appliance, uninterruptible power supply (UPS), energy storage system, or other battery-powered electronic device.

In some cases, in response to diagnosing the battery cells 210 as rapidly degrading (e.g., “Class 1”), an alert indicative of rapid degradation at the respective battery rack may be generated. In some cases, the alert may be displayed on a display or screen (e.g., an LCD monitor). The alert may comprise information identifying the respective battery cell, and may be transmitted by email, SMS, or pager, or other notification to a user (for example, to a computing device, cell phone, or pager).

In some cases, the alert includes a direction to perform an action to mitigate or replace the rapidly degrading battery cell. In some cases, the action may be automated so that it is performed automatically. In some cases, the action may be performed manually (e.g., by one or more members of a maintenance team). In some cases, the action may include at least one of: inspecting connections of the battery cell, disconnecting the battery cell, discharging the battery cell, or replacing the battery cell.

In the above, the present disclosure has been described in more detail through the drawings and aspects. However, the configurations described in the drawings or the aspects in the specification are merely aspects of the present disclosure and do not represent all the technical ideas of the present disclosure. Thus, it is to be understood that there may be various equivalents and variations in place of them at the time of filing the present application which are encompassed by the claims.

What is claimed is:

1. A system for diagnosing rapidly degrading battery cells, comprising:
a controller comprising a processor and a non-transitory memory storing computing instructions which when executed by the processor is configured to:
(a) apply a direct current (DC) pulse to a battery cell during at least one of a charging process or a discharging process;
(b) measure a change in voltage over time in response to the applied DC pulse to determine direct current internal resistance (DCIR);
(c) isolate a charge transfer resistance (R_{ct}) component of the DCIR by excluding an ohmic resistance (Rₒ) component from the DCIR; and
(d) diagnose the battery cell as rapidly degrading based on the R_{ct} component by predicting at least one state of health (SOH) of the battery cell indicative of rapid cell degradation.

2. The system of claim 1, wherein step (d) comprises:
input the R_{ct} component as a feature into a classifier to predict the at least one SOH of the battery cell at 180 charge-discharge cycles and 270 charge-discharge cycles; and
diagnose the battery cell as rapidly degrading when a difference of the predicted SOH at 270 charge-discharge cycles and the predicted SOH at 180 charge-discharge cycles is at least about 2.5%.

3. The system of claim 2, wherein the classifier is a linear regression model that implements elastic net (EN) regression.

4. The system of claim 1, wherein the controller is configured to determine the DCIR at multiple timescales of the DC pulse including 0.1 seconds and at least one of 10 seconds or 30 seconds,
wherein step (c) comprises subtracting the DCIR measured at 0.1 seconds from the DCIR measured at the at least one of 10 seconds or 30 seconds to exclude the Rₒ component and isolate the R_{ct} component.

5. The system of claim 1, wherein the controller is configured to apply the DC pulse after one or more of 0, 90, 180, or 270 charge-discharge cycles of the battery cell.

6. The system of claim 1, wherein the controller is configured to determine the DCIR at one or more timescales of the applied DC pulse, wherein the one or more timescales comprise 0.1 seconds, 1 seconds, 5 seconds, 10 seconds, 15 seconds, 20 seconds, 25 seconds, 30 seconds, or 60 seconds.

7. The system of claim 1, wherein the controller is configured to determine the DCIR at one or more states of charge (SOC) of the battery cell, wherein the one or more SOC comprise 10, 20%, 30%, 40%, 50%, 60%, 70%, 80% or 90%.

8. The system of claim 1, wherein the controller is configured to apply the DC pulse during a hybrid pulse power characterization (HPPC) test at multiple states of charge (SOC); and determine multiple values of the DCIR from the HPPC test, wherein the HPPC test comprises applying the DC pulse with at least two different currents.

9. The system of claim 8, wherein the at least two different currents comprise at least two of 0.5C, 1C, 1.5C, 2.0C, or 2.5C.

10. The system of claim 1, wherein the battery cell is configured to power an electric vehicle, and the controller is integrated with a battery management system (BMS) of the electric vehicle.

11. A method for diagnosing rapidly degrading battery cells, comprising:
(a) applying a direct current (DC) pulse to a battery cell during at least one of a charging process or a discharging process;
(b) measuring a change in voltage over time in response to the applied DC pulse to determine direct current internal resistance (DCIR);
(c) isolating a charge transfer resistance (R_{ct}) component of the DCIR by excluding an ohmic resistance (Rₒ) component from the DCIR; and
(d) diagnosing the battery cell as rapidly degrading based on the R_{ct} component by predicting at least one state of health (SOH) of the battery cell indicative of rapid cell degradation.

12. The method of claim 11, wherein step (d) comprises:
inputting the R_{ct} component as a feature into a classifier to predict the at least one SOH of the battery cell at 180 charge-discharge cycles and 270 charge-discharge cycles; and
diagnosing the battery cell as rapidly degrading when a difference of the predicted SOH at 270 charge-discharge cycles and the predicted SOH at 180 charge-discharge cycles is at least about 2.5%.

13. The method of claim 12, wherein the classifier is a linear regression model that implements elastic net (EN) regression.

14. The method of claim 11, wherein the DCIR is determined at multiple timescales of the DC pulse including 0.1 seconds and at least one of 10 seconds or 30 seconds, wherein step (c) comprises subtracting the DCIR measured at 0.1 seconds from the DCIR measured at the at least one of 10 seconds or 30 seconds to exclude the Rₒ component and isolate the Rot component.

15. The method of claim 11, wherein the DC pulse is applied after one or more of 0, 90, 180, or 270 charge-discharge cycles of the battery cell.

16. The method of claim 11, wherein the DCIR is determined at one or more timescales of the applied DC pulse, wherein the one or more timescales comprise 0.1 seconds, 1 seconds, 5 seconds, 10 seconds, 15 seconds, 20 seconds, 25 seconds, 30 seconds, or 60 seconds.

17. The method of claim 11, wherein the DCIR is determined at one or more states of charge (SOC) of the battery cell, wherein the one or more SOC comprise 10, 20%, 30%, 40%, 50%, 60%, 70%, 80% or 90%.

18. The method of claim 11, wherein the DC pulse is applied during a hybrid pulse power characterization (HPPC) test at multiple states of charge (SOC); and multiple values of the DCIR are determined from the HPPC test, wherein the HPPC test comprises applying the DC pulse with two or more different currents.

19. A non-transitory computer-readable medium having computer-executable instructions stored thereon that, in response to execution by a processor of a controller, cause the controller to perform operations for diagnosing rapidly degrading battery cells, the operations comprising:
(a) applying a direct current (DC) pulse to a battery cell during at least one of a charging process or a discharging process;
(b) measuring a change in voltage over time in response to the applied DC pulse to determine direct current internal resistance (DCIR);
(c) isolating a charge transfer resistance (R_{ct}) component of the DCIR by excluding an ohmic resistance (Rₒ) component from the DCIR; and
(d) diagnosing the battery cell as rapidly degrading based on the R_{ct} component by predicting at least one state of health (SOH) of the battery cell indicative of rapid cell degradation.

20. The non-transitory computer-readable medium of claim 19, wherein step (d) comprises:
inputting the R_{ct} component as a feature into a classifier to predict the at least one SOH of the battery cell at 180 charge-discharge cycles and 270 charge-discharge cycles; and
diagnosing the battery cell as rapidly degrading when a difference of the predicted SOH at 270 charge-discharge cycles and the predicted SOH at 180 charge-discharge cycles is at least about 2.5%.
